(19) United States
(12) Patent Application Publication
(10) Pub. No.: US 2005/0074948 A1
(43) Pub. Date: Apr. 7, 2005

(54) Method of manufacturing shallow trench isolation structure using HF vapor etching process

(76) Inventors: Hyung-Ho Ko, Seoul (KR); Woo-Gwan Shim, Gyeonggi-do (KR); Yu-Kyung Kim, Busan Metropolitan City (KR); Chang-Ki Hong, Gyeonggi-do (KR); Sang-Jun Choi, Seoul (KR)

Correspondence Address: MARGER JOHNSON & MCCOLLOM, P.C., 1030 SW MORRISON STREET, PORTLAND, OR, 97205, US

(21) Appl. No.: 10/949,426

(22) Filed: Sep. 24, 2004

(30) Foreign Application Priority Data
Oct. 7, 2003 (KR) 2003-69727

(51) Int. Cl. H01L 21/76

(52) U.S. Cl. 438/424; 438/435

(57) ABSTRACT

In a method of manufacturing a shallow trench isolation (STI) structure using a HF vapor etching process according to some embodiments of the invention, a trench is formed in a semiconductor substrate. A buffer layer and a first insulating layer, which fill the trench, are formed. A portion of the first insulating layer is removed by performing an etching process using HF vapor, thereby removing a void existing in the first insulating layer. A second insulating layer filling the trench is formed on the etched first insulating layer. Other embodiments of the invention are described and claimed.

### CROSS REFERENCE TO RELATED APPLICATIONS

This application claims priority from Korean Patent Application No. 2003-69727, filed on 7 Oct. 2003 in the Korean Intellectual Property Office, the content of which is incorporated by reference in its entirety for all purposes.

### BACKGROUND OF THE INVENTION

1. Field of the Invention

This disclosure relates to a method of manufacturing a semiconductor device, and more particularly, to a method of manufacturing a shallow trench isolation (STI) structure using a HF vapor etching process to effectively remove a void without damaging other portions of the device.

2. Description of the Related Art

When forming devices on a semiconductor substrate, isolation is first introduced to define an active region where a device is formed on the semiconductor substrate. Such isolation is usually implemented by STI with the reduction of a design rule. However, during manufacture of an STI structure, when a trench is filled with an insulating material, voids may frequently occur in an isolation layer made of the insulating material. The occurrence of voids increases as an aspect ratio of a trench for STI increases in proportion with the reduction of a design rule.

FIG. 1 is a cross-sectional diagram illustrating how a void may occur during a conventional STI forming processes.

Referring to FIG. 1, in conventionally forming an STI structure, a trench 15 is formed in a semiconductor substrate 10. Next, the trench 15 is filled with an insulating layer 35 that is then planarized. Here, a mask 20 made of silicon nitride (Si₃N4) is used as an etch mask for forming the trench 15 and as a stopper during planarization of the insulating layer 35. A pad oxide layer 21 may be introduced below the mask 20. A buffer layer 31 composed of silicon nitride is disposed between the insulating layer 35 and an inner wall of the trench 15.

In this situation, since the aspect ratio of the trench 15 increases significantly with the reduction of a design rule, a void 37 occurs when the trench 15 is filled with the insulating layer 35. This void 37 is exposed on a surface of the STI structure when the insulating layer 35 is planarized. The void 37 exposed on the surface of the STI structure may cause faulty operation of a device formed on the semiconductor substrate 10. Therefore, the void 37 must be removed. For this reason, various methods for preventing occurrence of the void 37 have been proposed, and some of them seem to be very effective.

However, as the reduction of a design rule continues, a process margin that enables prevention of the void 37 becomes very small. In particular, in a single-layer structure, it is very difficult to form the insulating layer 35 filling the trench 15 without producing the void 37.

In addition to preventing occurrence of the void 37, other factors, including security of the buffer layer 31, should be considered in order to preserve effective STI characteristics. The buffer layer 31 is essential for effective STI characteristics. The buffer layer 31 performs a very important function such as compensating for a stress at an interface between the insulating layer 35 filling the trench 15 and a material of the semiconductor substrate 10 corresponding to the inner wall of the trench 15. Accordingly, when the trench 15 is filled with the insulating layer 35 without the void 37, the buffer layer 31 should be protected from damage.

Therefore, a method of filling the trench 15 with the insulating layer 35 without producing the void 37 and damaging the buffer layer 31 is desired.

### SUMMARY OF THE INVENTION

Embodiments of the invention provide methods of manufacturing a shallow trench isolation (STI) structure that effectively remove voids and that prevent a buffer layer from being damaged.

### BRIEF DESCRIPTION OF THE DRAWINGS

The above and other features and advantages of the invention will become more apparent by describing in detail exemplary embodiments with reference to the attached drawings that are briefly described below.

FIG. 1 is a cross-sectional diagram illustrating how a void may occur during a conventional shallow trench isolation (STI) forming processes.

FIG. 2 is a flowchart illustrating a method of manufacturing an STI structure according to some embodiments of the invention.

FIGS. 3 through 7 are cross-sectional diagrams illustrating stages in a method of manufacturing an STI structure according to some embodiments of the invention.

FIGS. 8A and 8B are cross-sectional diagrams illustrating in further detail structures that can be provided by a method of manufacturing an STI structure according to some embodiments of the invention.

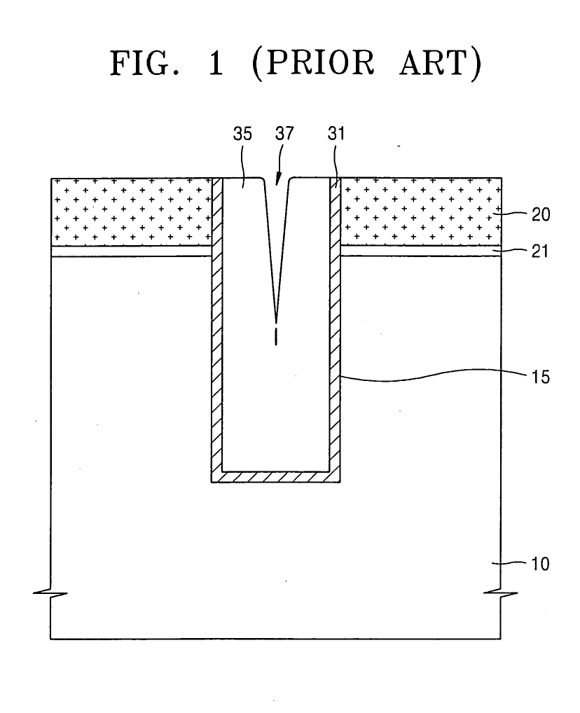

### DETAILED DESCRIPTION OF THE INVENTION

In the paragraphs below, exemplary embodiments of the invention will be described in detail with reference to the attached drawings.

Embodiments of the invention provides a method of manufacturing a shallow trench isolation (STI) structure, by which a void can be effectively removed. When an insulating layer filling a trench for STI is formed, a first insulating layer is formed to initially fill the trench. Next, the first insulating layer is partially etched to remove a void, which occurs in the first insulating layer when the first insulating layer is formed. Here, an etching process is preferably performed using HF vapor as an etchant in order to effectively prevent a buffer layer that is formed between the first insulating layer and the trench from being lost or damaged.

A HF vapor etching process is performed by providing a gas including HF vapor with H₂O vapor onto the first insulating layer. Accordingly, the HF vapor etching process is performed in a single wafer chamber. In a schematic model of the HF vapor etching process, HF vapor dissolves in a water film formed by H₂O vapor on a surface of the first insulating layer, thereby generating a HF solution. Then, the HF solution reacts with the silicon oxide that is preferably found in the first insulating layer, thereby etching the first insulating layer from the surface thereof.

The HF vapor etching process is advantageous for realizing a relatively higher etch rate for the silicon oxide found in the first insulating layer that fills the trench for STI and for realizing a relatively lower etch rate for the silicon nitride found in the buffer layer. In other words, an advantage of a high etch selectivity with respect to silicon nitride can be obtained by using an HF vapor etching process. As a result, when the first insulating layer formed of silicon oxide is etched, the buffer layer formed of silicon nitride can be effectively prevented from being lost or damaged during the etching process.

If the buffer layer is damaged while the first insulating layer is being etched, the buffer layer cannot function as a buffer. For example, the buffer layer can not alleviate a stress between a semiconductor substrate material forming the trench, i.e., silicon (Si), and a second insulating layer material that is deposited on the first insulating layer, i.e., silicon oxide. In addition, when the buffer layer is thinned or lost at an entrance of the trench, the refresh characteristic of the device, e.g., a transistor in a dynamic random access memory (DRAM) device, may deteriorate.

The undesirable loss or damage of the buffer layer that is formed of silicon nitride frequently occurs when the first insulating layer is partially and directly etched with a conventional wet etching process that uses a diluted HF solution or a buffered oxide etchant (BOE). In the wet etching process using a BOE, an etch rate with respect to silicon oxide is so high that the first insulating layer has poor uniformity. As a result, the depth of the trench, i.e., the thickness of the first insulating layer is not uniform after is etched. Therefore, a height of an STI structure is not uniform. Accordingly, it is very difficult to correctly configure an STI process scheme or STI process conditions when a wet etching process that uses BOE is performed. When the wet etching process directly uses a diluted HF solution, it is difficult to realize a high etch selectivity with respect to silicon nitride, and therefore, damage to the buffer layer that is formed of silicon nitride for STI is unavoidable.

However, when a HF vapor etching process according to an embodiment of the invention is used to partially etch the first insulating layer for STI, a high etch selectivity with respect to silicon nitride can be realized so that loss or damage of the buffer layer formed of silicon nitride can be effectively prevented. In addition, a very high etch rate can be realized with respect to silicon oxide, and the etch uniformity and the depth uniformity can be improved. Accordingly, a process margin sufficient to remove a void can be more effectively secured.

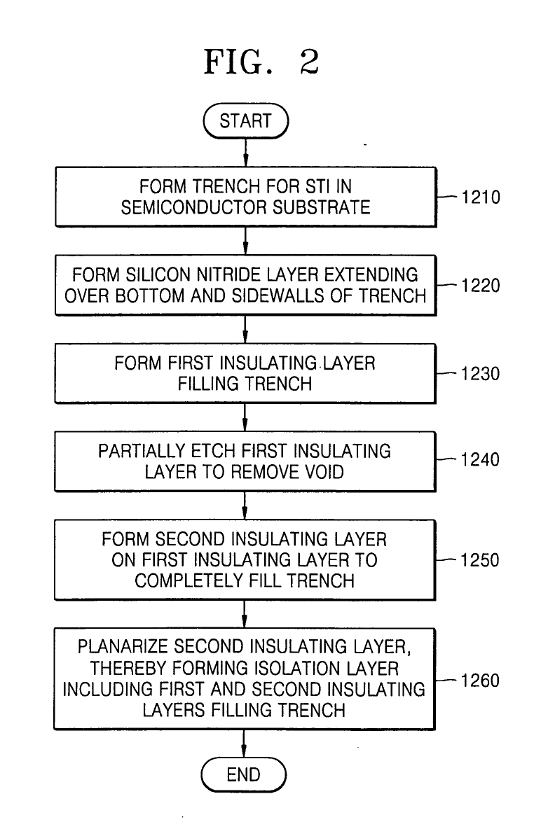

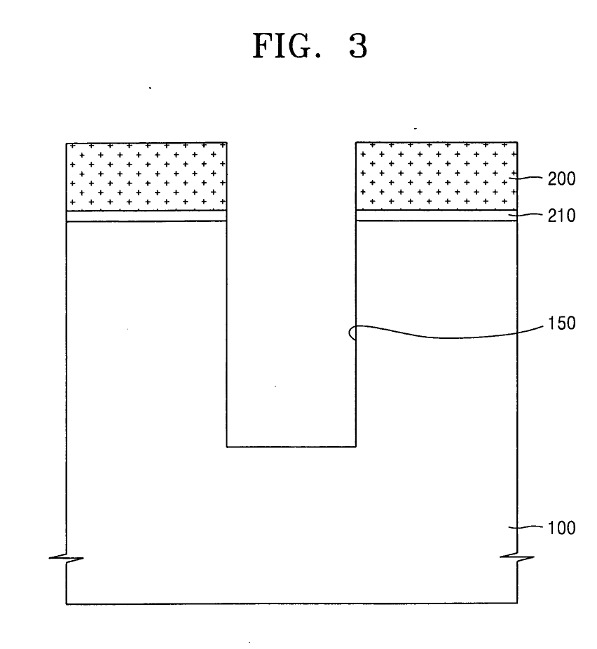

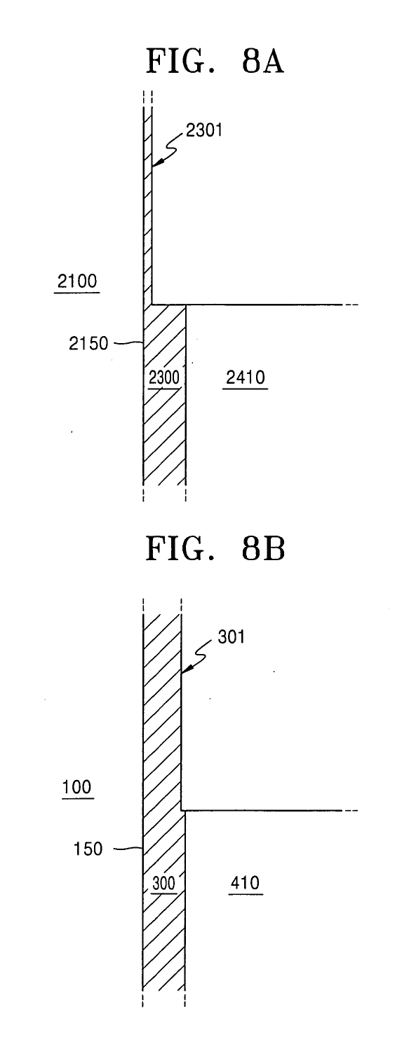

FIG. 2 is a flowchart illustrating a method of manufacturing an STI structure according to some embodiments of the invention. FIGS. 3 through 7 are cross-sectional diagrams illustrating stages in the method of manufacturing an STI structure according to some embodiments of the invention. FIGS. 8A and 8B are cross-sectional diagrams illustrating in further detail the structures that can be provided by the method of manufacturing an STI structure according to some embodiments of the invention.

Referring to FIGS. 2 and 3, in process 1210, a trench 150 for STI is formed in a semiconductor substrate 100 that is preferably formed of silicon. For example, a pad oxide layer 210 is formed as a thermal oxide layer on the semiconductor substrate 100, and a silicon nitride layer is formed as an etch mask 200 on the pad oxide layer 210. The etch mask 200 functions as a stopper during subsequent planarization, e.g., during subsequent chemical mechanical polishing (CMP). Thereafter, the semiconductor substrate 100 is selectively etched using the etch mask 200, thereby forming the trench 150 to a predetermined depth in the semiconductor substrate 100.

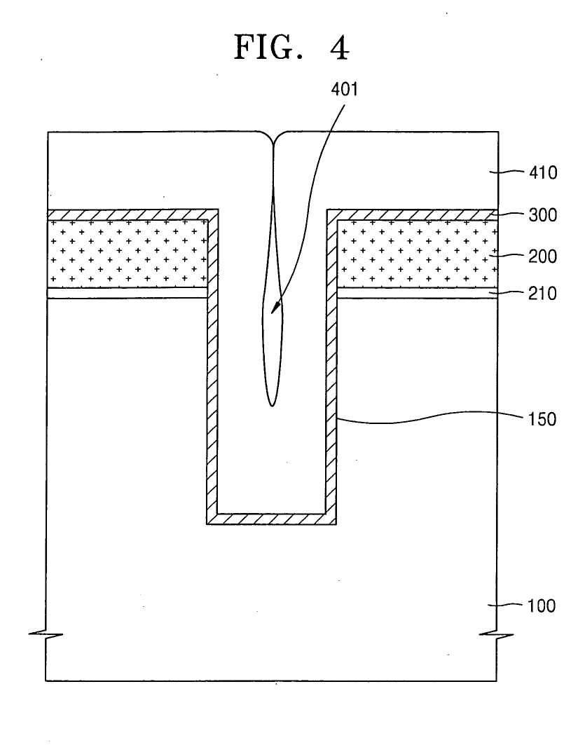

Referring to FIGS. 2 and 4, in process 1220, a buffer layer 300 is formed to cover the resultant structure illustrated in FIG. 3, which includes the bottom and the sidewalls of the trench 150. The buffer layer 300 is introduced to improve STI characteristics, e.g., such as the alleviation of stress. It is preferable that the buffer layer 300 is composed of a silicon nitride layer. A different type of insulating layer, e.g., a silicon oxide layer, may be formed on the top and the bottom surfaces of the buffer layer 300 in order to prevent oxidation or to improve interface characteristics.

Next, in process 1230, the trench 150 is filled with a first insulating layer that is formed on the buffer layer 300. The first insulating layer 410 may be formed using a material having a high gap filling characteristic, such as a high-temperature undoped silicate glass (USG), a high density plasma (HDP) oxide, or a silicon oxide such TOSZ. Here, a void 401 may occur within the first insulating layer 410 due to an increase in an aspect ratio of the trench in accordance with a rapid reduction of a design rule. When a critical dimension (CD) of the trench 150 is rapidly decreased, the frequency of occurrence of the void 401 also rapidly increases.

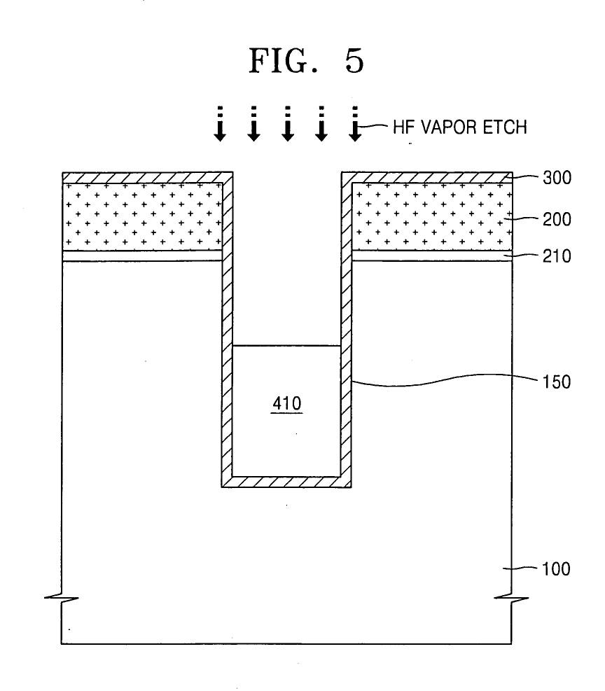

Referring to FIGS. 2 and 5, in process 1240, the first insulating layer 410 is partially etched, thereby removing the void 401. The first insulating layer 410 is etched using a HF vapor etching process. For example, after the semiconductor substrate 100 is supplied into a single wafer process chamber, HF vapor with H₂O vapor is supplied onto the semiconductor substrate 100 so that the first insulating layer 410 can be selectively etched. Preferably, anhydrous HF vapor is used since it is advantageous in process control.

In addition, a gas containing an alcohol group or a carboxyl group may be provided together with the H₂O vapor. The gas containing an alcohol group may be isopropyl alcohol (IPA), methyl alcohol (CH₃OH), or ethyl alcohol. The gas containing a carboxyl group may be carboxylic acid (CH₃COOH) vapor. These gases are used to accelerate the etching process by the HF vapor. In other words, they are catalysts in the HF vapor etching process.

When the gas containing the alcohol group or the carboxyl group is provided, and in particular, when the gas containing the alcohol group together with the HF vapor and the H₂O vapor is provided, the gas containing the alcohol group, i.e., an ROH gas (where R indicates a reactor) reacts with the HF vapor, thereby activating the HF vapor, and functions as a catalyst when the activated HV vapor is reacted with silicon oxide, thereby inducing a by-product, ROH, in a vapor state. Accordingly, the amount of water produced as a by-product of the reaction can be reduced as compared to a case where only the H₂O vapor is provided together with the HF vapor. In addition, since ROH is volatilized better than water, the by-product can be effectively prevented from remaining on a surface of an etched structure.

When etching the first insulating layer 410 using the HF vapor etching process, a partial etch is performed by continuing to etch up until the point that the void 401 is removed from the first insulating layer 410. Due to the etching process, a surface of the buffer layer 300 positioned on the sidewalls of the trench 150 is exposed. However, since the HF vapor etching process according to the embodiments of the invention can realize a silicon nitride-to-silicon oxide etch selectivity of 1/100 or less, loss or damage of the buffer layer 300 that is formed of silicon nitride can be effectively prevented.

In an experiment that was performed to test an embodiment of the invention, vapor was supplied to a process chamber at a rate of 180 Standard Cubic Centimeters per Minute (SCCM) and H₂O vapor was supplied to the process chamber at a rate of 2.5 liters/minute. In this case, high-temperature USG and silicon nitride were etched by about 2800 Å and 21 Å, respectively, for about 80 seconds. Here, a semiconductor substrate had a temperature of about 60° C. In a comparison experiment that tested a conventional method, a wet etch using a HF solution diluted at a rate of 100:1 was performed for about 350 seconds. In this case, the high-temperature USG and silicon nitride were etched by about 2800 Å and 128 Å, respectively. The results of the experiments prove that silicon nitride is etched much less by embodiments of the invention than by the conventional wet etch using a diluted HF solution while the high-temperature USG is etched by the same amount in either process.

Meanwhile, when a wet etch using a HF solution diluted at a rate of 100:1 was performed for about 90 seconds, a thermal oxide that is known to be a very stable film material was etched by about 200 Å. To etch thermal oxide by about 200 Å using an HF vapor etching process according to an embodiment of the invention, HF vapor and H₂O vapor were supplied at rates of 180 SCCM and 2.5 liters/minute, respectively, for about 15 seconds. Under these conditions, high-temperature USG was etched by about 720 Å in the wet etching process and by about 514 Å by the embodiment of the invention. Here, silicon nitride was etched by about 33 Å in the wet etching process and by about 4 Å by the embodiment of the invention.

The results of the experiments described above prove that only a very small amount of silicon nitride is etched in an HF vapor etching process according to embodiments of the invention as compared to a conventional wet etching process. However, the amount of silicon oxide, e.g., high-temperature USG, that is etched in both the HF vapor etching process according to embodiments of the invention and in the conventional wet etching process is the same. Accordingly, as shown in FIG. 5, when the first insulating layer 410 is partially etched using a HF vapor etching process, the buffer layer 300, which is formed of silicon nitride and is exposed during the etching process, can be effectively prevented from being lost and damaged.

Preventing the loss and damage of the buffer layer 300 is important to maintaining and improving STI characteristics. As shown in FIG. 8A, if the silicon nitride that forms a buffer layer 2300 is removed when a first insulating layer 2410 is removed, an etched silicon nitride layer portion 2301 of the buffer layer 2300 is very thin.

Usually, a desirable thickness of a buffer layer is about 50-78 Å. When the thickness of the buffer layer 2300 decreases to the point shown in the silicon nitride layer portion 2301 in FIG. 8A, the buffer layer 2300 cannot function properly. High-temperature USG that is used as an insulating material of the first insulating layer 2410 may be etched and removed by about several hundreds or thousands of angstroms to remove a void. In this case, as described above with reference to the data obtained from the experiments using conventional wet etching, the buffer layer 2300 formed of silicon nitride may be etched by a maximum of several hundreds of angstroms. Accordingly, the silicon nitride layer portion 2301 of the buffer layer 2300 ceases to function as a buffer. In this situation, a large amount of stress is induced at an interface between a material of a semiconductor substrate 2100 forming sidewalls of a trench 2150 and the silicon oxide, i.e., an insulating layer, that is used to fill the trench 2150 after the etching process. As a result, the STI characteristics may deteriorate, which may cause poor operating or refreshing characteristics of a memory device, e.g., a DRAM device.

However, as shown in FIG. 8B, even when a silicon nitride layer portion 301 of the buffer layer 300 is exposed while the first insulating layer 410 is etched, since a HF vapor etching process according to embodiments of the invention provides a very low etch rate with respect to silicon nitride as proved by the data obtained from the above-described experiments, the silicon nitride layer portion 301 that is exposed during the etching process maintains a sufficient thickness to function as the buffer layer 300. In other words, as is seen from the data of the experiments, even when the first insulating layer 410 is etched by about 2800 Å, the exposed silicon nitride layer portion 301 is only slightly removed by about 21 Å. Accordingly, when the buffer layer 300 includes a silicon nitride layer having a thickness of about 78 Å, the exposed silicon nitride layer portion 301 can maintain a thickness of at least 57 Å. This fact proves that embodiments of the invention can secure a minimum thickness of about 50 Å that is required for a buffer layer in an STI structure.

Referring back to FIG. 5, since HF vapor needs to be supplied during the HF vapor etching process that is used to partially etch the first insulating layer 410, the process may be performed in a single wafer process chamber. Here, anhydrous HF vapor may be supplied at a flow rate of about 100-2000 SCCM, and the semiconductor substrate 100 may be maintained at a temperature of about 0-60° C. In addition, a catalyst gas such as IPA may be supplied at a flow rate of 50-200 SCCM.

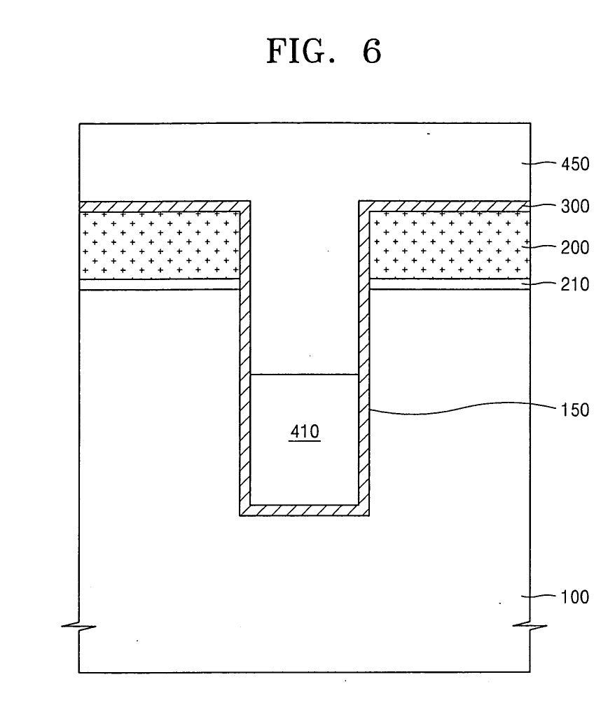

Referring to FIGS. 2 and 6, in process 1250, a second insulating layer 450 is formed on the partially etched first insulating layer 410 to completely fill the trench 150, which is now without a void. The second insulating layer 450 may be formed of high-temperature USG, HDP oxide, or silicon oxide such as TOSZ, which has a high gap filling characteristic. Since the aspect ratio of the trench 150 that is to be filled with the second insulating layer 450 is remarkably decreased due to a presence of the first insulating layer 410 remaining after the void 401 shown in FIG. 4 is removed by partial etching, the second insulating layer 450 can be formed to fill the trench 140 without a void. However, if the aspect of ratio of the trench 150 is still high and a void occurs again, the process of forming the first insulating layer 410 and partially etching the first insulating layer 410 to remove the void may be repeated.

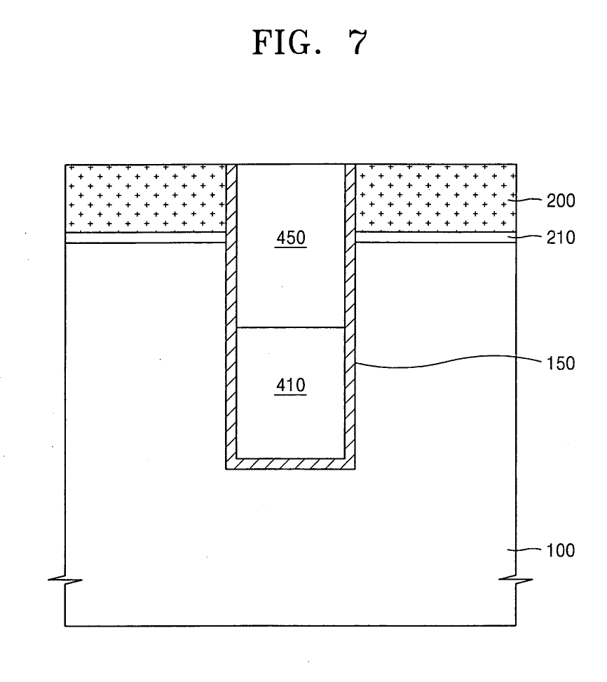

Referring to FIGS. 2 and 7, in process 1260 a surface of the second insulating layer 450 is planarized, thereby forming an isolation layer including the first and second insulating layers 410 and 450 that are confined to the trench 150. As such, an STI structure is realized. To planarize the second insulating layer 450, CMP may be used, and the etch mask 200 that is formed of silicon nitride may be used as a stopper.

As described above, according to embodiments of the invention, a void can be effectively removed when manufacturing an STI structure so that STI without voids can be realized. Since a HF vapor etching process is used to partially etch an insulating layer formed of silicon oxide filling a trench in order to remove a void, a silicon nitride layer formed as a buffer layer between the insulating layer and sidewalls of the trench can be effectively prevented from being lost or damaged. Accordingly, deterioration of STI due to damage on the silicon nitride layer that forms the buffer layer can be prevented. In addition, since the HF vapor etching process provides high etch uniformity with respect to silicon oxide, uniformity of STI can be improved.

The invention may be practiced in many ways. What follows are exemplary, non-limiting descriptions of some embodiments of the invention.

In a method of manufacturing a shallow trench isolation structure according to some embodiments of the invention, a trench is formed in a semiconductor substrate. The trench is filled with a first insulating layer. Before forming the first insulating layer, a buffer layer is positioned between a wall of the trench and the first insulating layer. The buffer layer may include a silicon nitride layer. A portion of the first insulating layer is selectively removed with respect to the buffer layer by performing an etching process using HF vapor, thereby removing a void that exists in the first insulating layer. The trench is filled by forming a second insulating layer on the etched first insulating layer.

The selective removal of the portion of the first insulating layer may be performed in a single wafer process chamber. The selective removal of the portion of the first insulating layer may include supplying the HF vapor onto the first insulating layer at a flow rate of about 100-2000 SCCM. The selective removal of the portion of the first insulating layer may also include supplying H₂O vapor together with the HF vapor. A gas containing an alcohol group may be supplied together with the H₂O vapor. The gas containing an alcohol group may be supplied onto the first insulating layer at a flow rate of about 50-200 SCCM. The gas containing an alcohol group may be isopropyl alcohol (IPA), methyl alcohol, or ethyl alcohol.

Selectively removing the portion of the first insulating layer may further include supplying a gas that contains a carboxyl group together with the H₂O vapor. The gas that contains a carboxyl group may be carboxylic acid vapor. Selectively removing the portion of the first insulating layer may further include maintaining the semiconductor substrate at a temperature of about 0-60° C. Selectively removing the portion of the first insulating layer may further include supplying a gas containing an alcohol group or a carboxyl group together with the HF vapor.

Although the specification may refer to “an”, “one”, “another”, or “some” embodiment(s) in several locations, this does not necessarily mean that each such reference is to the same embodiment(s), or that the feature only applies to a single embodiment. Furthermore, while this invention has been particularly shown and described with reference to preferred embodiments thereof, it will be understood by those skilled in the art that various changes in form and details may be made therein without departing from the spirit and scope of the invention as defined by the appended claims.

1. A method of manufacturing a shallow trench isolation structure, comprising:
forming a trench in a semiconductor substrate;
forming a first insulating layer filling the trench;
forming a buffer layer positioned between a wall of the trench and the first insulating layer before forming the first insulating layer;
selectively removing a portion of the first insulating layer with respect to the buffer layer by performing an etching process using HF vapor, thereby removing a void existing in the first insulating layer; and
forming a second insulating layer filling the trench on the etched first insulating layer.

2. The method of claim 1, wherein selectively removing the portion of the first insulating layer is performed in a single wafer process chamber.

3. The method of claim 1, wherein selectively removing the portion of the first insulating layer comprises supplying the HF vapor onto the first insulating layer at a flow rate of about 100-2000 SCCM.

4. The method of claim 1, wherein selectively removing the portion of the first insulating layer comprises supplying H₂O vapor together with the HF vapor.

5. The method of claim 4, wherein selectively removing the portion of the first insulating layer comprises supplying a gas containing an alcohol group together with the H₂O vapor.

6. The method of claim 5, wherein the gas containing an alcohol group is supplied onto the first insulating layer at a flow rate of about 50-200 SCCM.

7. The method of claim 5, wherein the gas containing an alcohol group is isopropyl alcohol (IPA).

8. The method of claim 5, wherein the gas containing an alcohol group is either of methyl alcohol and ethyl alcohol.

9. The method of claim 4, wherein selectively removing the portion of the first insulating layer comprises supplying a gas containing a carboxyl group together with the H₂O vapor.

10. The method of claim 9, wherein the gas containing a carboxyl group is carboxylic acid vapor.

11. The method of claim 1, wherein selectively removing the portion of the first insulating layer comprises maintaining the semiconductor substrate at a temperature of about 0-60° C.

12. The method of claim 1, wherein selectively removing the portion of the first insulating layer comprises supplying a gas containing an alcohol group together with the HF vapor.

13. The method of claim 1, wherein selectively removing the portion of the first insulating layer comprises supplying a gas containing a carboxyl group together with the HF vapor.

14. The method of claim 1, wherein the buffer layer comprises a silicon nitride layer.

15. A method comprising:
removing a portion of a semiconductor substrate to form a trench;
depositing a buffer layer on a sidewall and a bottom of the trench;
filling a remainder of the trench with a first insulating layer;
until a void in the first insulating layer is removed, etching a portion of the first insulating layer using HF vapor while simultaneously preventing the buffer layer from reaching a thickness less than 50 Å; and
filling the trench with a second insulation layer formed on the etched first insulating layer.

16. The method of claim 15, wherein etching the portion of the first insulating layer comprises supplying an additional gas mixture together with the HF vapor, the additional gas mixture consisting of at least one selected from the group consisting of H₂O vapor, a gas containing an alcohol group, and a gas containing a carboxyl group.

17. The method of claim 16, wherein the gas containing an alcohol group is selected from the group consisting of isopropyl alcohol, methyl alcohol, and ethyl alcohol.

18. The method of claim 16, wherein the gas containing a carboxyl group consists of carboxylic acid vapor.
